(19) United States
(12) Patent Application Publication
(10) Pub. No.: US 2026/0176526 A1
(43) Pub. Date: Jun. 25, 2026

(54) Light-Emitting Electronic Module for a Chip Card

(71) Applicant: Smart Packaging Solutions, Rousset (FR)

(72) Inventors: Bernard Calvas, Rousset (FR); Sebastien Marmugi, Rousset (FR); Maxime Di Bernardo, Rousset (FR)

(21) Appl. No.: 18/712,604

(22) PCT Filed: Nov. 22, 2022
(86) PCT No.: PCT/FR2022/000116

§ 371 Date: May 22, 2024

(30) Foreign Application Priority Data
Nov. 24, 2021 (FR) 2112431

(51) Int. Cl. C09K 11/06; H10W 72/20; H10W 90/00

(52) U.S. Cl. CPC C09K 11/06; H10W 72/20; H10W 90/00; H10W 90/724; H10W 90/734; H10W 90/754; H10W 90/756

(57) ABSTRACT

Example embodiments relate to light-emitting electronic modules for chip cards. One example electronic module is configured to be integrated into a cavity in the body of a chip card. The electronic module includes a dielectric substrate having, on a first face, a terminal strip for electrical contacts enabling operation through contact with the corresponding contacts of a chip card reader. The dielectric substrate includes at least one luminescent agent integrated directly into the material of the dielectric substrate and visible, or able to be rendered visible, in gaps between the electrical contacts or through an opening formed in an electrical contact of the electronic module.

The invention relates to a light-emitting electronic module for a chip card, and to a chip card incorporating such a module.

### PRIOR ART

The chip-card electronic module market is constantly seeking technical solutions for improving the modules. In the field of chip cards intended for banking applications and for applications concerned with identifying the card bearer, the key objectives targeted are generally concerned with increasing the security of the cards against attempts at counterfeiting, or replacing an authentic module with a counterfeit module, or else with visual customisation of the electronic modules so that they fit better with the colorschemes employed by the various issuers of cards.

In this respect, attempts have already been made in the prior art at introducing colored zones into a visible part of the modules.

Thus, document FR 2964488 A1 makes provision for adding an LED under the epoxy substrate of the module in order to backlight the module when the module is electrically powered. That entails drawing energy from the radiofrequency circuit of the module in order to power the LED, and this has an impact on the radiofrequency communications performance of the electronic module of the chip card.

That method exhibits other constraints which greatly limit its benefit and use in practice. Specifically, the electronic module needs to have a large enough surface area to accept and position an LED in addition to the microelectronic chip that manages security, which precludes the application of this technique to small-sized modules. Furthermore, the material of the substrate of the module needs to be transparent to visible light or at least translucent, in order to allow the light emitted by the LED to pass, and this kind of substrate is more expensive than the usual opaque substrates. These restrictions explain why, despite there being a very large number of chip cards in service, few, if any, in actual fact incorporate an LED for security or cosmetic customization purposes.

Elsewhere, document FR 3063414 B1 describes an electronic module for a chip card, which module is provided with a dielectric substrate, with an electrical circuit comprising ISO 7816 contacts and with an adhesive applied between the substrate and the electrical circuit. That document therefore teaches the addition of a colorant to the adhesive situated between the substrate and the metal contacts.

This technique also has a number of disadvantages. Specifically, the colored gaps between the contacts of the module remain constantly visible. Therefore, if the color of the adhesive in the gaps between the metal contacts were to be used for security purposes, that use would not be very discreet because in order to be effective, a security device generally needs to be discreet.

Once it has been identified as a security device, the permanent coloration of the gaps can fairly easily be replicated by counterfeiters in order to produce counterfeit electronic modules. The colored adhesive may also be removed and replaced after heating and removing the module.

Moreover, simple coloration of the adhesive visible at the gaps in the ISO contacts of the module is ultimately not very visible when lighting conditions are not optimal, for example in relatively poorly lit environments. This is notably because a coloration is visible by simply reflecting ambient light in one zone of the visible-light spectrum.

Also, document WO 2015/049610 A1 discloses a chip card structure comprising a multilayer body one of the layers of which may comprise a security element, notably in the form of luminescent pigments. Therefore, that document does not envision integrating luminescent pigments directly into the electronic module intended to be integrated into a cavity in the chip card body, or into the epoxy substrate of the electronic module. Therefore, the security element described in that document may be visible only from the card body and neither from gaps situated between the contacts of the electronic module nor through an opening made in a contact of the electronic module.

### OBJECTIVES OF THE INVENTION

A general objective of the invention is therefore to propose a chip-card electronic module capable of overcoming the disadvantages of the modules according to the prior art.

One particular objective of the invention is to propose a chip-card electronic module which is provided with a security pattern that is normally invisible part that becomes visible only intermittently or on demand upon inspection.

Another particular objective of the invention is to propose an electronic module having a security pattern the duration of visibility of which can easily be adapted to suit the intended applications of the chip card.

Another objective of the invention is to propose an electronic module that is as easy to produce as the existing modules, without appreciable additional cost.

Another objective of the invention is to propose an electronic module that does not call into question the conventional and proven chip-card production methods, namely the simple transferring of the electronic module into a cavity in the card body, using existing machines.

### SUMMARY OF THE INVENTION

In principle, the invention consists in integrating a luminescent agent directly into the dielectric matrix of the printed circuit of the electronic module, namely typically a substrate made of epoxy glass. The luminescent agent may notably consist of a particular pigment, or of a suitable combination of pigments.

Unlike a simple passive reflection of light off a colorant, as is known practice in chip cards according to the state of the art, luminescence is an active phenomenon embodied by the emission of photons, and this emission can be controlled in terms of wavelength or in terms of duration through an appropriate choice of the luminescent agents used, thereby, in practice, providing a wide diversity of uses.

Furthermore, this solution makes it possible to benefit from the wide diversity of types of luminescence in existence. It may for example be photoluminescence in response to illumination from a UV lamp, fluorescence, phosphorescence, etc. The luminescent agent employed may also be selected to obtain luminescence that is normally invisible but that is rendered visible according to specific lighting conditions or according to other environmental conditions. Conversely, the luminescent agent may be selected such that it is visible by default, but rendered invisible by a change in lighting or in some other environmental factor.

The distribution and dosage of the pigments or other luminescent agents form a specific luminescence spectrum identifiable by a security laboratory, or more simply visible when illuminated by a beam of UV light.

The subject matter of the invention is therefore an electronic module intended to be integrated into a cavity in the body of a chip card, this electronic module comprising a dielectric substrate having, on a first face, a terminal strip for electrical contacts enabling operation through contact with the corresponding contacts of a chip card reader, characterized in that it comprises at least one luminescent agent integrated directly into the material of the dielectric substrate and visible, or able to be rendered visible, in gaps between the electrical contacts or through an opening formed in an electrical contact of the electronic module.

According to one embodiment, said dielectric substrate comprises several layers of material and said luminescent agent is therefore incorporated into at least one of the layers of the substrate and visible from a visible face of the electronic module.

According to one embodiment, said luminescent agent is visible, or able to be rendered visible, in gaps between the electrical contacts or through an opening formed in an electrical contact of the terminal strip.

According to one embodiment, said luminescent agent is able to change appearance under the effect of excitation transmitted via the environment.

Said change in appearance may notably consist in a change in reflectivity, in transparency or in brightness of a visible part of the substrate.

According to the invention, said luminescent agent is chosen to change appearance under the effect of a physical-chemical excitation selected notably from illumination under natural light or under ultraviolet light, a change in ambient temperature, or a change to the chemical environment of the module.

According to embodiment variants, said luminescent agent is selected to produce an irreversible change in appearance, or a change in appearance that is reversible, or temporary of predetermined duration.

According to embodiment variants, said luminescent agent is selected to exhibit a luminescence effect either for short periods of time of less than a few milliseconds, so as to be invisible to the human eye, or for long periods of time in order to ensure remanent visibility, for example lasting several hours or days.

Depending on the embodiment, said luminescent agent consists of at least one luminescent pigment selected from fluorescent, photoluminescent, phosphorescent, chemiluminescent or thermoluminescent pigments.

In particular, said luminescent agent may be a photoluminescent pigment selected to become visible under lighting of ultraviolet wavelength.

According to one embodiment, said luminescent pigment is selected to be normally invisible but capable of being revealed as visible under predetermined environmental conditions.

According to one embodiment, said luminescent agent is selected to produce a change in appearance that is reversible, or temporary of predetermined duration.

According to one embodiment, use is made of a luminescent agent or of a combination of several luminescent pigments which are selected to emit luminescence in a first range of wavelengths under UV excitation, and emit in another range of wavelengths under another excitation.

Alternatively, it is possible to use a single luminescent pigment emitting a first color under UV excitation, and another color when placed in the dark.

According to one embodiment, the luminescent agent is contained within protective capsules that are opaque to visible light and/or light in the ultraviolet spectrum, which is to say wavelengths comprised between 380 and 750 nanometers in the case of the visible spectrum, and between 120 and 380 nanometers in the case of the UV spectrum, the luminescent agent being able to be activated or deactivated when the electronic module is scanned with a laser beam. These protective capsules may be single-layer or multi-layer and made from materials that are substantially fluidtight, or at the very least that offer a barrier against moisture and/or a thermal barrier. As a result, they are able to prevent the luminescent agent from undergoing hydrolysis or from suffering degradation due to excessive temperature.

According to one embodiment, said luminescent agent contains thermochromic pigments which become visible as a result of a release of heat during an electronic transaction.

According to one embodiment, said luminescent agent contains a collection of differentiated pigments, the distribution and dosage of which are chosen to form a specific luminescence spectrum identifiable by visual examination or a security laboratory.

According to one embodiment, said luminescent agent is visible through a window in one face of the module, in the form of a logo, a security pattern, or an alphanumeric character.

According to one embodiment, the main color of the luminescence of the luminescent agent is the same as the color of the card body.

Another subject matter of the invention is a chip card, characterized in that it comprises an electronic module as described above.

Other features and advantages of the invention will become apparent upon reading the detailed description and the appended drawings, in which:

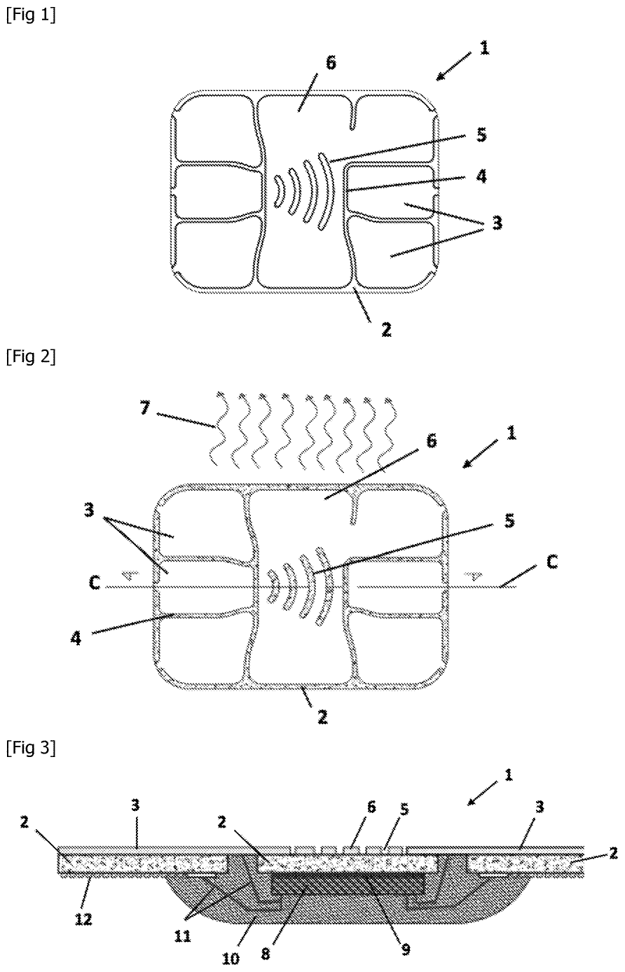

FIG. 1 is a plan view of an electronic module for a chip card, comprising a luminescent substrate according to a first embodiment of the invention, and illuminated under natural light;

FIG. 2 is a plan view of an electronic module for a chip card, according to a second embodiment of the invention, comprising a phosphorescent substrate;

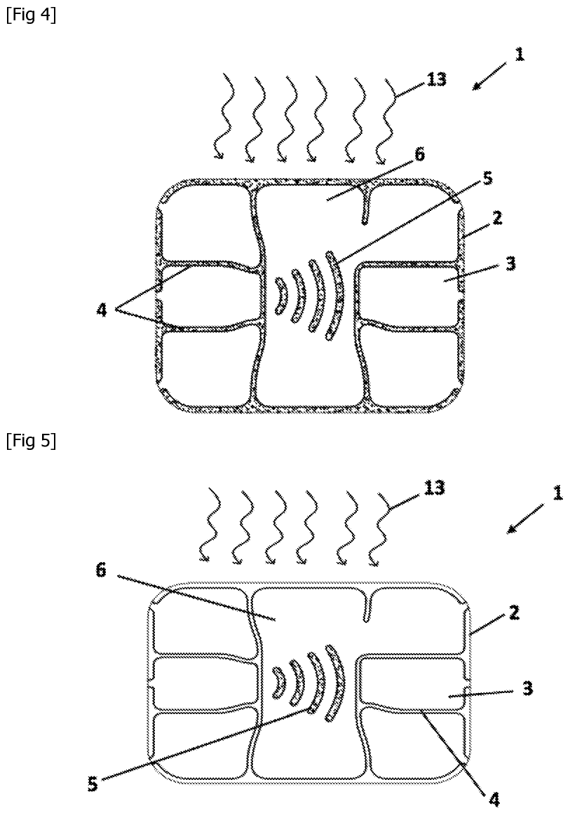

FIG. 3 shows a cross-sectional view of the electronic module of FIG. 2;

FIG. 4 is a plan view of a third embodiment of an electronic module according to the invention, provided with a luminescent substrate that is sensitive to ultraviolet illumination;

FIG. 5 is a plan view of a modified version of the electronic module of FIG. 4.

### DETAILED DESCRIPTION

FIG. 1 depicts a plan view of an electronic module 1 for a chip card, according to a first embodiment of the invention. This module 1 comprises a substrate 2 to which there is bonded a metal film forming contacts 3 in accordance with the ISO 7816 format enabling interaction with the corresponding contacts of a chip card reader. The substrate 2 is visible through gaps 4 between the metal contacts 3 and at cutouts 5 formed in the central metal contact 6.

According to the invention, the substrate 2 of the electronic module incorporates a luminescent agent directly into its mass, and the surface of the module 1 comprises at least one zone in which this luminescent substrate is visible. In the example depicted in FIG. 1, the visible zone of the substrate corresponds to the gaps 4 between the metal contacts 3, and to cutouts 5 in the central metal part 6 of the electronic module. In this particular instance, these cutouts 5 correspond to a logo symbolizing that the module also supports contactless operation. Of course, absolutely any other form of cutout 5 in the metal film (pattern, logo, alphanumeric character, etc.) might suit, provided that it allows the luminescent substrate 2 to show. In the example of FIG. 1, the substrate 2 is luminescent under simple illumination with natural light, in the visible spectrum.

There are a number of conceivable methods for rendering the substrate 2 luminescent.

Luminescence is an emission of light referred to as “cold” as opposed to incandescence which is referred to as “warm”. The light emitted by luminescence is the result of interactions between electrically charged particles. Most usually, it is electron transitions occurring within atoms, molecules or crystals that give rise to the emission of photons. The energy released in the form of light during the transition may initially be supplied in electrical, chemical, mechanical, thermal or luminous form. A distinction between different types of luminescence is made on the basis of the initial mode of excitation.

Moreover, fluorescence and phosphorescence are two different forms of luminescence, which can be distinguished from one another notably in terms of the duration of the emission of light following excitation: fluorescence ceases very quickly, lasting perhaps a few microseconds and therefore remaining invisible to the human eye, whereas phosphorescence persists for longer. One phenomenon or the other may be selected according to the intended application.

The luminescent agent may notably be selected from among the fluorescent compositions described in document WO 2019202278 A1.

According to other manufacturing examples, the luminescent agent may consist of inorganic materials doped with ions of rare earths or transition metals. These may notably be glasses or crystals (aluminate, silicate, titanate, fluoride) doped with ions such as Europium Eu3+, Cerium Ce3+, le Manganese Mn4+, Chromium Cr3+, according to known doping methods.

The luminescent agent may even consist of strontium alloys doped with Europium ions, or a yttrium aluminum garnet (YAG) glass or crystal doped with Erbium, Neodymium, or Cerium.

According to other exemplary embodiments, the luminescent agent may consist of quantum effect semiconductor materials, or of fluorochromic organic-inorganic complexes or organic materials, containing either rare earths or aromatic amino acids (for example phenylalanine), polyphenols (for example gallic acid), chlorophylls or aromatic heterocycles (for example tetraphenylporphyrin).

It is also possible to use combinations of the aforementioned luminescent agents, thereby making it possible to vary the luminescence effects according to the effects desired.

By way of example, materials that will emit luminescence in a first range of wavelengths under UV excitation and then another range of wavelengths when placed in the dark, may be combined.

Certain luminescent agents are sensitive to temperature or to ambient humidity. It may therefore be beneficial to protect them by enclosing them in protective capsules made of silica, alumina or a fluidtight polymer such as a polyolefin. That will make it possible to prevent the luminescent agent from undergoing hydrolysis or from suffering degradation due to excessive temperature, and will enable good transparency to UV excitation to be maintained.

The encapsulation may also be performed in a thermoplastic material such as a polyolefin, the advantage of which lies in the fact that it can be melted at a fairly low temperature (for example 145° C. to 175° C. in the case of a polypropylene) in order to locally deactivate the luminescence.

The luminescent agent thus formed and protected is distributed through the dielectric substrate of the printed circuit of the electronic module for a chip card, which thus becomes luminescent under exposure to UV light.

Alternatively, the encapsulation of the luminescent agent is performed using a material that is opaque at the wavelengths of the excitation or of the emission and that can be degraded, for example, upon the passage of a laser beam. The encapsulation may be multilayer depending on the desired effect, for example so as to activate a zone under the effect of UV excitation, while maintaining insulation against moisture and/or against temperature.

Depending on the combination selected for the luminescent agents, the life of the luminescence is chosen to be fairly short and practically stops with exposure, or else so that it extends after excitation so as to be able to emit for a number of hours.

In order to obtain a long-lasting radiative effect following UV or visible excitation, one solution is to co-dope the host crystal that forms the substrate of the integrated circuit using a second dopant. Strontium aluminate may for example be co-doped with a second dopant consisting of ions of Dysprosium Dy3+. The second dopant therefore fills the crystal defects near the conduction band of the host dopant to form traps to trap the released electrons. The additional material introduced in the form of the co-dopant will therefore allow emission to be sustained for longer.

According to one embodiment, the main color of the luminescence may be the same as that of the card body, or else a color that contrasts with that of the card body.

Moreover, the structure of the substrate 2 made of dielectric material may be monolithic or else multilayer. In the latter instance, the luminescent material will be integrated into a layer of the substrate 2 that is visible on the external face of this substrate, either directly, or through another, superposed, layer which will then be transparent or provided with a cutout.

The luminescent pigments themselves may be contained in capsules that are opaque to UV radiation and able to be degraded when marked with a laser ray, for example during a module customization phase. In that case, a laser scanning of the surface of the module, particularly of the potentially luminescent zone (such as the zone of the gaps 4 or of the cutouts 5) will enable the release of the pigments and the activation of the localized luminescence of the module. This method will also allow serialization of the modules by using laser-beam scanning that is differentiated between successive modules or between successive groups of modules.

Conversely, the pigments selected may be initially luminescent and then selectively destroyed as a laser ray passes over them, so that the substrate zone scanned by the laser will no longer be luminescent after it has been scanned.

According to another conceivable variant, use will be made of phosphorescent pigments which charge in daylight and emit light when placed in the dark.

According to another conceivable variant, it might be possible to make the luminescence of the module dependent upon its involvement in a transaction performed with the chip card. By way of example, the use, in the substrate, of thermochromic pigments, will enable their luminescence to be activated using the heat released in a transaction with the chip card in front of a radiofrequency reader.

In the example depicted in FIG. 2, which is similar to the example of FIG. 1, the substrate 2 integrates an agent that is luminescent through phosphorescence, and which, at the gaps 4 and the cutouts 5, emits visible photons schematically indicated by the arrows 7.

FIG. 3 depicts a view of the electronic module of FIG. 2 in cross section on a plane of section denoted C-C. In the known way, this module 1 comprises a metal terminal strip exhibiting contact zones 3, 6 which are bonded to the upper face of the substrate 2. A microelectronic chip 8 is bonded to the lower face of the substrate 2, by means of a thin layer of adhesive 9. The lower face of the substrate 2 also bears the coils 12 of an antenna. The module in this particular instance is therefore a hybrid module supporting contact and contactless operation with the chip card reader. The connection pads of the communication interfaces of the microelectronic chip 8 are connected by conducting wires 11 either to the rear face of the metal terminals 3 or to the ends of the antenna 12. In the known way, the microelectronic chip 8 and its connections to the metal terminals 3 or to the antenna 12 are protected by a drop of encapsulation resin 10.

According to the invention, the substrate 2 of the electronic module is not a substrate made from a conventional dielectric material such as pure epoxy. Rather, the dielectric material directly incorporates in its mass luminescent agents in the form of particles which have been indicated by dots distributed randomly through the thickness of the substrate 2. These luminescent agents are notably selected from among those mentioned hereinabove, but entirely nonlimitingly.

FIG. 4 depicts an embodiment of an electronic module similar to that of FIG. 2, but the phosphorescent substrate has been replaced by a substrate 2 integrating an agent that is luminescent under ultraviolet illumination, indicated schematically by the arrows 13. The visible zones 4, 5 of the substrate respond to this ultraviolet excitation with a luminescence effect that will be dependent on the luminescent agents used in the substrate 2.

FIG. 5 depicts an embodiment similar to that of FIG. 4, except that the luminescent agents are no longer integrated across the entirety of the surface of the substrate 2 but only into a zone of the substrate 2 that is situated beneath the cutouts 5 of the central zone 6 of the module.

Of course, many other embodiments are possible in practice, while remaining within the context fixed by the present invention.

### ADVANTAGES OF THE INVENTION

Ultimately, the invention achieves the aims which were set. It makes it possible to improve the security of electronic modules for chip cards against attempts at counterfeiting, because of the integration into the substrate of the module itself of highly specific pigments that can be activated or deactivated on demand by UV lamp or a specific laser beam, and/or detected by ad hoc inspection means.

Furthermore, the luminescence effect can be activated or deactivated on demand, or intermittently.

No LED or equivalent needs to be integrated into the module, so the solution according to the invention has no negative impact on the radiofrequency performance of the module and of the chip card.

Moreover, the integration of luminescent pigments into the substrate of the module has no impact on the method for assembling the module into the body of the chip card. In this respect, in order to manufacture a chip card it suffices merely to transfer the module provided with its luminescent substrate into a chip card body, this being easy to do at low cost and with a high degree of reliability with the majority of conventional chip-implanting machines used for manufacturing contact chip cards.

1. An electronic module configured to be integrated into a cavity in the body of a chip card, the electronic module comprising a dielectric substrate having, on a first face, a terminal strip for electrical contacts enabling operation through contact with the corresponding contacts of a chip card reader, wherein the dielectric substrate comprises at least one luminescent agent integrated directly into the material of the dielectric substrate and visible, or able to be rendered visible, in gaps between the electrical contacts or through an opening formed in an electrical contact of the electronic module.

2. The electronic module of claim 1, wherein the dielectric substrate comprises several layers of material, and wherein the luminescent agent is incorporated into at least one of the layers of the dielectric substrate and visible on a visible face of the electronic module.

3. The electronic module of claim 1, wherein the luminescent agent is able to change appearance under the effect of excitation transmitted via the environment.

4. The electronic module of claim 3, wherein the change in appearance comprises a change in reflectivity, transparency, or brightness of a visible part of the dielectric substrate.

5. The electronic module of claim 1, wherein the luminescent agent is configured to change appearance under the effect of a physical-chemical excitation from illumination under natural light or under ultraviolet light, a change in ambient temperature, or a change to the chemical environment of the electronic module.

6. The electronic module of claim 1, preceding wherein the luminescent agent is configured to produce an irreversible change in appearance.

7. The electronic module of claim 1, wherein the luminescent agent is configured to produce a change in appearance that is reversible or temporary with a predetermined duration.

8. The electronic module of claim 7, wherein the luminescent agent is configured to exhibit a luminescence effect for short periods of time of less than a few milliseconds so as to be invisible to the human eye or for long periods of time in order to ensure remanent visibility.

9. The electronic module of claim 1, wherein the luminescent agent comprises a fluorescent pigment, a photoluminescent pigment, a phosphorescent pigment, a chemiluminescent pigment, or a thermoluminescent pigment.

10. The electronic module of claim 1, wherein the luminescent agent is a photoluminescent pigment configured to become visible under lighting of ultraviolet wavelength.

11. The electronic module of claim 1, wherein the luminescent pigment is configured to be normally invisible but capable of being revealed as visible under predetermined environmental conditions.

12. The electronic module of claim 10, claims 10 further comprising a luminescent agent or combination of agents configured to; emit luminescence in a first range of wavelengths under UV excitation and emit luminescence in another range of wavelengths when placed in the dark.

13. The electronic module of claim 1, wherein the luminescent agent is contained within protective capsules that are opaque to visible light or light in the ultraviolet spectrum, and wherein the luminescent agent is able to be activated or deactivated when the electronic module is scanned with a laser beam.

14. The electronic module of claim 13, wherein the protective capsules are single-layer or multi-layer and made from materials that offer a barrier against moisture or a thermal barrier, able to prevent the luminescent agent from undergoing hydrolysis or from suffering degradation due to excessive temperature.

15. The electronic module of claim 1, wherein the luminescent agent contains thermochromic pigments that become visible as a result of a release of heat during an electronic transaction.

16. The electronic module of claim 1, wherein the luminescent agent contains a collection of differentiated pigments, the distribution and dosage of which are chosen to form a specific luminescence spectrum identifiable by visual examination or a security laboratory.

17. The electronic module of claim 1, wherein the luminescent agent is visible through a window in one face of the module, in the form of a logo, a security pattern, or an alphanumeric character.

18. The electronic module of claim 1, wherein the main color of the luminescence is the same as that of the card body.

19. A security document, wherein the security document comprises the electronic module of claim 1.

20. The security document of claim 19, wherein the security document is a chip card.
